(19) United States
(12) Patent Application Publication
(10) Pub. No.: US 2004/0042323 A1
(43) Pub. Date: Mar. 4, 2004

(54) Removable storage device

(76) Inventor: Masoud Moshayedi, Newport Coast, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/448,881

(22) Filed: May 30, 2003

Related U.S. Application Data
(60) Provisional application No. 60/384,885, filed on May 31, 2002.

(51) Int. Cl. G11C 8/02

(52) U.S. Cl. 365/232

(57) ABSTRACT

An adapter for removable memory cards including a housing configured to receive a memory card, a connector for connection to a host system, an interface circuit interconnecting the memory card and connector and adapted to allow communication therebetween and at least one movable cover pivotably engaged with the housing and which, in a closed position, with the housing, defines a substantially enclosed cavity configured to retain the memory card. The adapter has a generally rounded and smooth outer contour and is relatively small and light weight to provide convenient carry on the person. The adapter is made of strong materials and by fully enclosing the memory card provides a physically robust removable storage device.

### RELATED APPLICATIONS

This application claims the benefit of priority of the U.S. provisional application No. 60/384,885 filed May 31, 2002 entitled “Fully Enclosed Compact Flash And Secure Digital Reader With USB Connector Protective Cap” which is incorporated herein in its entirety by reference.

### BACKGROUND OF THE INVENTION

1. Field of the Invention

The invention relates to the field of removable memory storage devices, such as adapters for removably receiving memory cards, for connection to a host system and, more particularly, to an enclosed adapter with a movable cover.

2. Description of the Related Art

Many electronic devices can create, receive, and/or process digitally coded information. This information is frequently maintained in operating memory for processing and stored to non-volatile memory for long-term storage and/or for storage when the device is powered down. Storage media has included magnetic discs and tapes, optical storage media such as CDs, and non-volatile solid-state memory, such as flash memory cards.

The wide variety and nature of electronic devices and their increasingly common presence in the workplace, at home, and as personal convenience devices carried on the person leads to frequent circumstances in which data that was stored, received, and/or processed on one device may be desired to be transferred to another device at the same or a different location. This need has resulted in the development of removable storage/memory devices embodied in media such as recordable compact discs, floppy discs, and solid state memory cards to allow stored data to be transferred from device to device. Many of these removable storage media however suffer the drawback that they are either relatively bulky, limited in storage capacity, and/or physically fragile. This has limited the ability for a person to readily carry an adequate storage capacity conveniently on the person, such as in a shirt or pants pocket.

Thus, there is an ongoing need for a removable data storage device that is relatively small, offers relatively large storage capacity, is physically robust, and configured for convenient, comfortable carry on the person. There is also a need for a removable storage device that can readily and inexpensively take advantage of ongoing advances and improvements, such as increased storage capacity and/or data transfer rate, in existent storage media. There is also a need for a removable storage device that is compatible with a variety of existent storage media and with media that may be developed that may offer cost, storage capacity, speed, and/or availability advantages compared to other storage media types.

### SUMMARY OF THE INVENTION

One embodiment of the invention is an adapter for removable memory cards, the adapter comprising a housing configured to receive a memory card, a connector for connection to a host system and connected to the housing, an interface circuit interconnecting the memory card and connector and adapted to allow communication therebetween, and at least one movable cover pivotably engaged with the housing and which, in a closed position, with the housing, defines a substantially enclosed cavity configured to retain the memory card.

The housing can be configured to receive a memory card. One example of a memory card that may be inserted in the housing is a solid state memory card. Two examples of solid state memory cards are Secure Digital (SD) memory cards and MultiMedia Cards (MMC). The housing can also be configured to receive a microdrive memory card or other removable memory card.

In one embodiment, at least one of the housing and cover comprise a securing structure to secure the cover in the closed position, such as a tab and corresponding recess. The securing structure can also comprise a friction fit, latch, detent, or other retaining structure in other embodiments.

The connector comprises a standard serial or parallel, wired or wireless connector. Examples of connector standards include Universal Serial Bus (USB), FireWire, Small Computer System Interface (SCSI), and Bluetooth. In other embodiments, the connector comprises a physical, non-wired connection, such as an optical connector.

The interface circuit can receive operating power from the host system. The cover can also be both pivotable and slidable with respect to the housing and, in one embodiment, at least one of the cover and housing has a region of non-zero transmittance such that the presence of the memory card in the reader may be visually determined.

The adapter can comprise a single cover or multiple covers. The cover or covers can be arranged in a clamshell configuration, overlapping, pivotable, and/or slidable configuration. The adapter can also include a removable connector cover or cap that substantially covers the connector. The connector cap can be tethered to the rest of the adapter. The adapter can also include an indicator which provides a signal when the adapter is operationally connected to the host system. Such an indicator can provide a signal when the memory card is in active communication with the host system.

Another embodiment of the invention is an adapter for removable memory cards, the adapter comprising a housing configured to receive a memory card, a connector for connection to a host system and connected to the housing, an interface circuit interconnecting the memory card and connector and adapted to allow communication therebetween, and at least one movable cover engaged with the housing wherein the cover and housing define a generally rounded exterior profile.

Yet another embodiment of the invention is a removable storage device connectable to a host system, the device comprising a memory card, a housing configured to receive the memory card, a connector for connection to a host system and connected to the housing, an interface circuit interconnecting the memory card and connector and adapted to allow communication therebetween, and at least one movable cover engaged with the housing such that the cover is pivotable with respect to the housing and, in a closed position, defines a substantially enclosed cavity configured to retain the memory card.

A further embodiment of the invention is a removable storage device connectable to a host system, the device comprising a memory card, a housing configured to receive the memory card, a connector for connection to a host system and connected to the housing, an interface circuit interconnecting the memory card and connector and adapted to allow communication therebetween, and at least one movable cover engaged with the housing wherein the cover and housing define a generally rounded exterior profile.

An additional embodiment of the invention is an adapter for removable memory cards, the adapter comprising a housing configured to receive a memory card, a connector for connection to a host system along a connection axis and pivotably connected to the housing along an axis substantially transverse to the connection axis, an interface circuit interconnecting the plurality of card contacts and connector and adapted to allow communication therebetween, and at least one movable cover engaged with the housing.

Yet another embodiment is an adapter for removable memory cards, the adapter comprising a housing configured to receive a memory card, a connector for connection to a host system and associated with the housing, an interface circuit interconnecting the memory card and connector and adapted to allow communication therebetween, and multiple movable covers which are pivotably engaged with the housing and which, in a closed position, with the housing, define a substantially enclosed cavity configured to retain the memory card.

A further embodiment is an adapter for removable memory cards, the adapter comprising a housing configured to receive a memory card and multiple movable covers which are pivotably engaged with the housing and which, in a closed position, with the housing, defines a substantially enclosed cavity configured to retain the memory card.

An additional embodiment is a memory card reader that interfaces with a universal serial bus (USB) connector, the memory card reader comprising a housing configured to receive different types of removable flash memory card, a USB connector connected to the housing, said USB connector configured to connect to a host system, interface circuitry that interconnects the different types of removable flash memory cards and the universal serial bus connector and is adapted to allow communication therebetween, and at least one movable cover pivotably engaged with the housing and which, in a closed position, with the housing, defines a substantially enclosed cavity configured to retain the removable flash memory card and which in an open position allows removal of the removable flash memory card.

In one embodiment, the invention provides a small, light-weight adapter with a smooth rounded outer profile that can receive a variety of memory cards and includes a full enclosure for the memory cards as well as common industry standard external connector and interface circuitry. An inexpensive, readily upgradable removable storage device is provided that is more physically rugged and smaller than other removable storage media and offers fast data access and high storage capacity.

In one embodiment, a cover for the memory card is provided that is connected to the rest of the adapter. The cover can include a pivoting and/or sliding interconnection to the rest of the adapter. The cover or other portions of the adapter can be formed at least partially of translucent or transparent material to allow a visual inspection of the interior of the adapter to confirm presence of a memory card therein or to determine information about the card. An optional cover can be included for the connector and the connector cover can be attached to the rest of the adapter. The connector is provided in common industry standard configurations for interchangeability with a variety of host systems. In certain embodiments, the connector is pivotably connected to the rest of the adapter to allow the body of the adapter to be moved for additional clearance in tight confines.

For purposes of summarizing the invention, certain aspects, advantages and novel features of the invention have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 is a perspective view of one embodiment of a removable storage device in a closed configuration;

FIG. 2 is an alternative perspective view of the removable storage device of FIG. 1;

FIG. 3 is a perspective view of a removable storage device embodied as an adapter with a memory card installed and a cover thereof in an open or distal position;

FIG. 4 is a perspective view of the removable storage device of FIG. 3 with the memory card removed from the adapter and showing a receiving area for the memory card;

FIG. 5 shows an alternative embodiment of a removable storage device with a cover both slidably and pivotably engaged with a housing thereof and in a closed configuration;

FIG. 6 is a perspective view of the removable storage device of FIG. 5 in a partially opened configuration;

FIG. 7 is a perspective view of the removable storage device of FIGS. 5 and 6 with the cover in an open configuration with a memory card removed therefrom;

FIG. 8 is a perspective view of an embodiment of a removable storage device with a cover pivotably engaged with a housing thereof and in an open configuration with a memory card removed therefrom;

FIG. 9 is a perspective view of a removable storage device with a connector cap covering a connector indicated in broken lines;

FIG. 10 is a perspective view of an embodiment of a removable storage device with a connector cap removed from the connector and attached to the rest of the removable storage device via a tether;

FIG. 11 is a perspective view of a removable storage device with a connector pivotably engaged therewith;

FIG. 12 is a perspective view of the removable storage device of FIG. 11 with the connector pivoted to an elevated position;

FIG. 13 is a perspective view of the removable storage device of FIG. 11 with the connector pivoted to a declinated position; and

FIG. 14 is a circuit diagram of one embodiment of an interface circuit adapted for interfacing a memory card to a host system, and in this embodiment via a USB connector.

### DETAILED DESCRIPTION OF THE PREFERRED EMBODIMENT

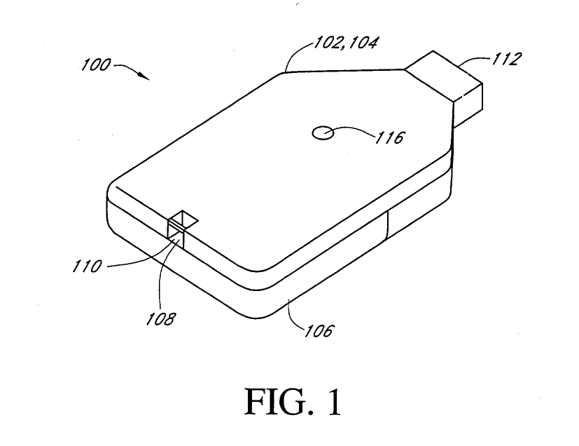

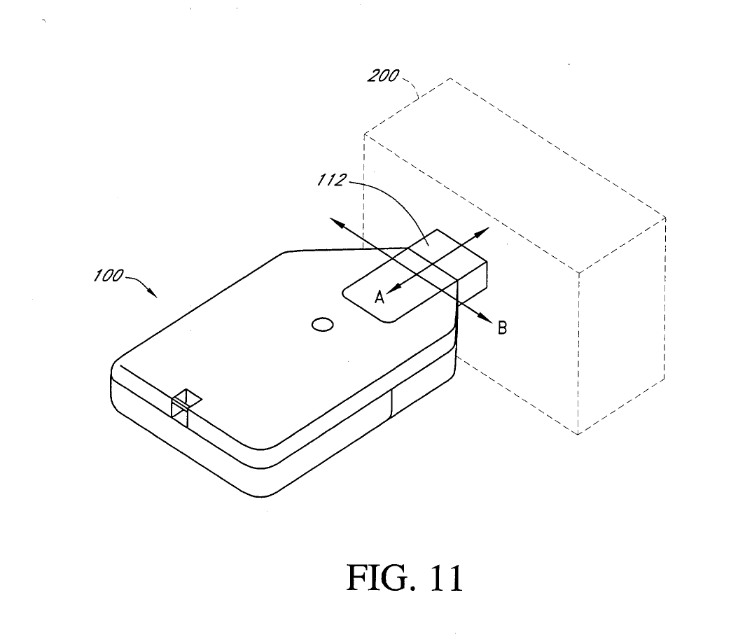

Reference will now be made to the drawings where like numerals refer to like parts throughout. FIG. 1 is a perspective view of one embodiment of a removable storage device 100. The removable storage device 100 is adapted to store digital information in a nonvolatile manner and is adapted for removable connection to a host system 200 shown in phantom in FIG. 11. In various embodiments, the host system 200 can comprise computer systems, digital still and/or movie cameras, personal digital assistants (PDAs), music players, game consoles, or other electronic devices which create, receive, process, and/or otherwise store digital information.

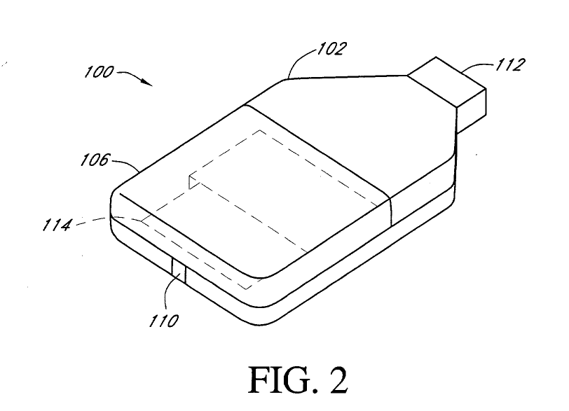

In one embodiment, the removable storage device 100 comprises an adapter 102 adapted to receive and communicate with a memory card 114 shown in phantom in FIG. 2. In one embodiment, the adapter 102 comprises a housing 104 and a cover 106. The cover 106 is movable with respect to the housing 104 and FIGS. 1 and 2 show the cover 106 in a closed position with respect to the housing 104.

In this embodiment, the adapter 102 also comprises a lanyard loop 108. The lanyard loop 108 is a through-going opening at one end of the housing 104. The lanyard loop 108 is configured to allow a strap, cord, chain, elastic cord or the like to thread through the lanyard loop 108 to provide an arrangement to allow the adapter 102 to be held via the strap, etc. The lanyard loop 108 also provides the capability to thread the adapter 102 onto a key-ring.

In certain embodiments, the adapter 102 comprises a securing structure 110 to retain the cover 106 in the closed configuration with respect to the housing 104. The securing structure 110 can comprise a tab and corresponding recess embodied in the cover 106 and housing 104 as shown in FIGS. 1 and 2, however in other embodiments, the securing structure 110 can comprise a peripheral snap fit, friction fit, latch, spring detent, or other retaining structures.

In certain embodiments, at least a portion of the adapter 102 is formed of a material with a non-zero transmittance, e.g. of a transparent or translucent material. In one particular embodiment, as is shown in FIG. 2, the cover 106 is made at least partially of a material having a non-zero transmittance, such as a translucent plastic material. This embodiment of the invention provides the advantage that a visual examination of the removable storage device 100 can confirm presence and proper placement of a memory card 114 within the adapter 102. Another advantage provided by this embodiment of the invention is that a visual examination of the removable storage device 100 can establish information regarding the memory card 114, such as, for example, the type and or storage capacity.

In one embodiment, the memory card 114 comprises a solid-state non-volatile memory card, such as a flash memory card. In specific embodiments therein, the memory card 114 comprises a Memory Stick card, a Secure Digital (SD) card, CompactFlash (CF) card, or a MultiMediaCard (MMC). In other embodiments, the memory card 114 comprises a Microdrive hard drive or other type of memory storage device. The memory card 114 offers the advantage of significantly greater storage capacity and reduced size than prior removable storage media, such as floppy disks. The memory card 114 also offers comparable data access rates and storage capacities as optical storage media, such as CDs or DVDs, but at reduced physical size. When embodied within the rest of the removable storage device 100, the memory card 114 is also more physically robust and protected from possible damage than floppy disks, CDs, or DVDs.

The removable storage device 100 also comprises a connector 112 for connection to a host system 200. In certain embodiments, the connector 112 provides both physical and electrical connection between the removable storage device 100 and the host system 200. The connector 112 is preferably configured as a common and industry standard connector to provide increased adaptability with a wide variety of different host systems 200. In some embodiments, the connector 112 provides a wired connection to the host system 200. In certain of these embodiments, the connector 112 comprises and conforms to a standard such as a Universal Serial Bus (USB), FireWire, or Small Computer System Interface (SCSI) connector or other connector type. The form factor and pin designations of wired connectors, such as the USB, FireWire, and SCSI connector standards are well known in the art and are illustrated here schematically and will not described in further detail.

In other embodiments, the connector 112 comprises a physical, non-wired connection such as an optical connection. In these embodiments the connector 112 preferably conforms to known industry standards for form factors, communication protocols, etc. In other embodiments, the connector 112 comprises a wireless connector. In these embodiments, the wireless connector 112 can communicate with the host system 200 via a radio frequency (RF), infrared (IR), or other electromagnetic frequency range link. One example of a wireless standard is the Bluetooth standard which is also well known and is illustrated here schematically and will not be described in greater detail. Of course, the Bluetooth wireless protocol is one embodiment of a wireless connector 112 and other embodiments can employ other wireless standards and protocols.

In certain embodiments, the removable storage device 100 also comprises an indicator 116 that can provide a signal indicative of the operation of the removable storage device 100. In certain embodiments, the indicator 116 provides a first signal indicative of proper connection of the connector 112 to a host system 200 and establishment of communication therebetween. In some embodiments, the indicator 116 provides a second signal indicative of active communication between the removable storage device and the host system 200. In one embodiment, the first signal comprises a steady illumination of a light and the second signal comprises an intermittent or blinking illumination of a light.

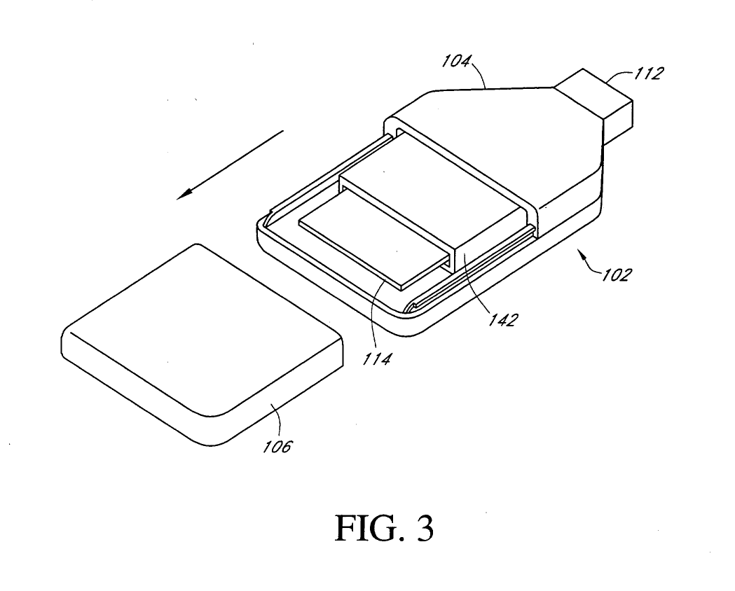

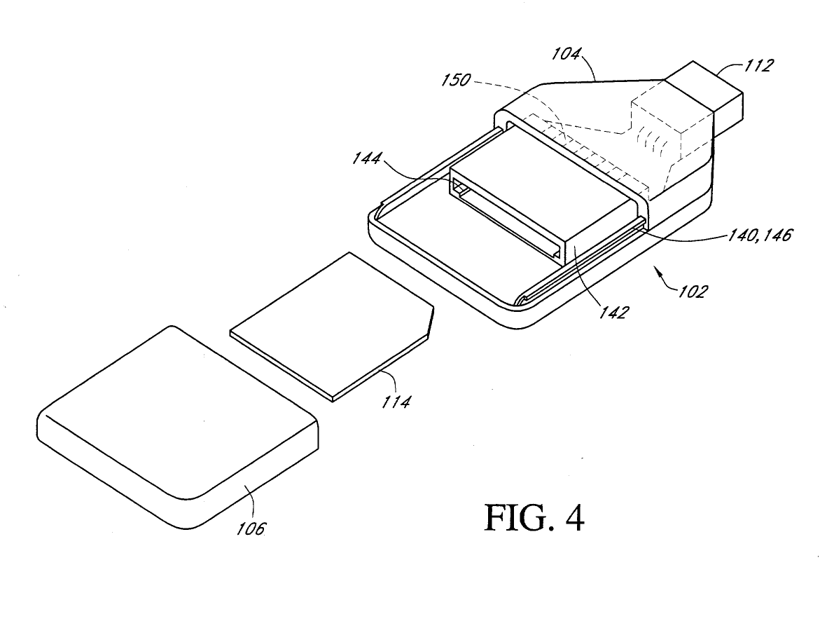

FIG. 3 illustrates one embodiment of an adapter 102 with the cover 106 in an open configuration providing access to the memory card 114. In the open configuration, a memory card 114 may be inserted or withdrawn from a receptacle 142 of the adapter 102. This embodiment of the invention provides increased economy as replacement memory cards 114 may be provided for additional storage capacity while utilizing a single adapter 102 rather than requiring purchase of a complete separate device including connector, memory, and interface circuitry. This embodiment of the invention also provides ready upgradability in that memory cards 114 of greater capacity or speed and/or reduced cost that become available may be inserted into the adapter 102 as shown in FIG. 4.

In this embodiment, the receptacle 142 comprises a metal shell configured to securely retain the memory card 114 and guide structures 144 that mate with corresponding structures of the memory cards 114 to facilitate proper orientation of the memory card 114 when inserted. The receptacle 142 is also mounted to a rigid circuit board 146 holding the interface circuit 140. The connector 112 is also mounted to the circuit board 146 which, together with the interconnected housing 104 and cover 106, physically protect and maintain in connection the memory card 114 and the connector 112. A plurality of contacts 150 are also provided within the receptacle 142 to provide electrical connection between the memory card 114 and the interface circuit 140 and thus with the connector 112. This embodiment allows the adapter 102 to act as a card reader to allow the host system 200 to interface with memory cards 114 via the connector 112, interface circuit 140 and contacts 150.

In this embodiment, the interface circuit 140 and circuit board 146 extend underneath the receptacle 142 and forward to the connector 112. In this embodiment, the length of the memory card 114 of approximately 3 cm is approximately half the overall length of the removable storage device 100 of approximately 7 cm. The width of the memory card (approximately 2.5 cm) is only approximately 1 cm less than the overall width of the removable storage device (approximately 3.5 cm).

The embodiment of the removable storage device shown in FIGS. 3 and 4 shows a slidable engagement between the cover 106 and housing 104 of the adapter 102. This slidable engagement is provided by cooperating slide and rail structures. The slide and rail structures may also comprise detent and corresponding recess structures to provide a securing structure 110 to retain the cover in the closed position. When the cover 106 is attached to the housing 104 in the closed position, the memory card 114 is encased and protected by at least two layers of rigid structure, in this embodiment, the housing 104, the circuit board 146, the receptacle 142, and the cover 106. When provided in addition to the encapsulation of the memory card 114 itself, the removable storage device 100 provides a physically robust environmental protection for the memory circuits of the memory card 114.

As can also be seen in FIGS. 1 and 2 for example, the removable storage device 100 comprises a generally rounded exterior profile. This embodiment of the invention reduces the presence of sharp corners and provides increased comfort and convenience to a user of the removable storage device. In particular, the avoidance of sharp corners as provided by the generally rounded and smooth outer contour of the removable storage device 100 makes the device 100 more comfortable to carry in a pocket. The rounded exterior profile of the removable storage device 100 also reduces wear and tear on materials that the device 100 may come in contact with, such as clothing or the contents of a purse or briefcase.

The exterior materials of the removable storage device 100 are preferably formed of a strong, lightweight material such as plastic. In certain embodiments, the exterior surfaces of the removable storage device 100 comprise, in addition or as an alternative, a resilient material. In these embodiments, the exterior material of the removable storage device 100 provides a degree of shock absorption in case of impact providing increased ruggedness to the removable storage device 100.

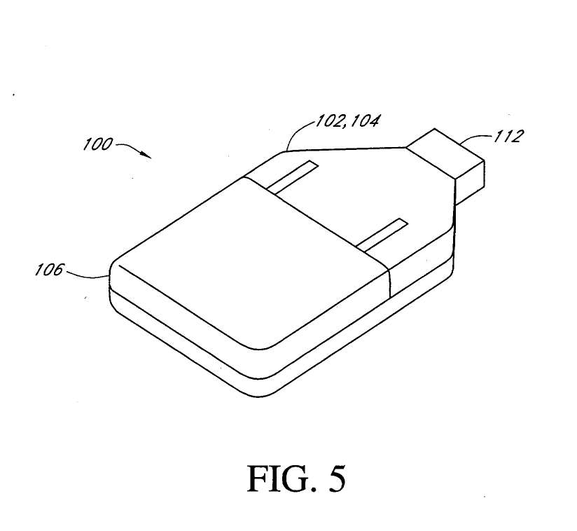

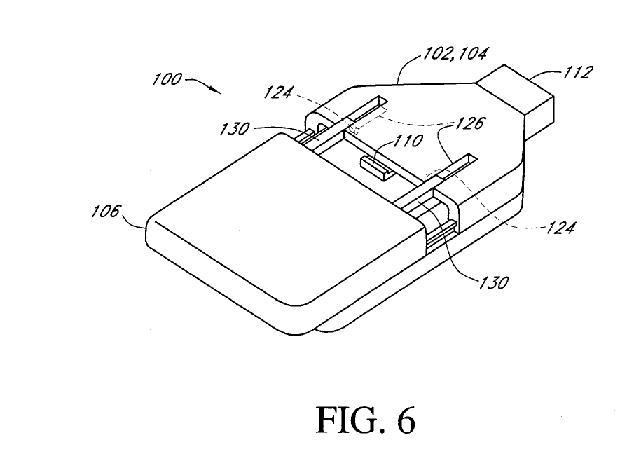

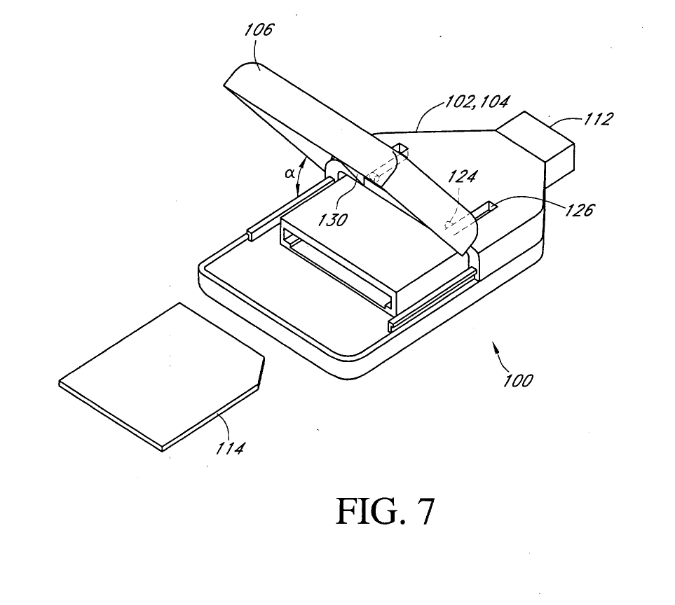

FIGS. 5-7 illustrate an alternative embodiment of a removable storage device 100 including a housing 104 and a cover 106 in a closed, partially opened, and open configuration respectively. In this embodiment, the cover 106 is both slidably and pivotably interconnected to the housing 104 via cooperating post 124 and slot structures 126. In this embodiment, the cover 106 includes a pair of legs 130 extending from an end of the cover 106 and the posts 124 are formed to extend inwardly from distal ends of the legs 130. As illustrated in FIGS. 6 and 7, the posts 124 are incorporated in the cover 106 and the cooperating slots 126 are embodied in the housing 104, however in other embodiments this relationship can be reversed. The posts 124 can be arranged to extend outwardly or both outwardly and inwardly in other embodiments.

In this embodiment, the cover 106 is moved from the closed configuration to the opened configuration by first sliding the cover 106 away from the housing 104 such that the posts 124 slide within the slots 126 and so as to release the securing structure 110. The cover 106 may then be pivoted upwards with the posts 124 rotating or pivoting within the slots 126 to expose the memory card 114 for insertion or removable. FIG. 7 illustrates the removable storage device 100 with the cover 106 in an open position and the memory card 114 removed. The cover 106 can pivot continuously through an angle α, such as approximately 90°, between the closed and open positions. FIG. 7 illustrates an intermediate open position with a of approximately 45°. In certain embodiments, detent positions are defined between the cover 106 and housing 104 to secure the cover 106 at specific angular relationships with the housing 104, such as an open position. While a single cover 106 is illustrated in FIGS. 5-7 for simplicity, in other embodiments, multiple and/or opposed covers 106 are provided. This embodiment can include a clamshell arrangement of the covers 106 with the covers 106 movable independently or in unison.

The legs 130 of this embodiment are substantially straight, however in other embodiments, the legs 130 are curved and fit into corresponding curved slots 126 in the housing 104. In such an embodiment, the legs 130 of the cover 106 slide within the curved slots 126 such that the cover 106 pivots up and away from the housing 104 also through an angle α, such as 0° through 180°. Of course the male/female relationship of the connection between the cover 106 and the housing 104 can be reversed in other embodiments.

In this embodiment, the securing structure comprises a latch or tab embodiment of the housing 104 with the corresponding recess or catch in the cover 106. It will be appreciated that in other alternative embodiments the relative arrangement of these structures may be reversed and/or other securing structures 110 such as friction fits, peripheral snap fits, or other retaining structures as previously discussed may be provided. Embodiments of the invention shown in FIGS. 5-7 include that the cover 106 is attached to the housing 104 to reduce the possibility of losing or misplacing the cover 106 of the removable storage device 100.

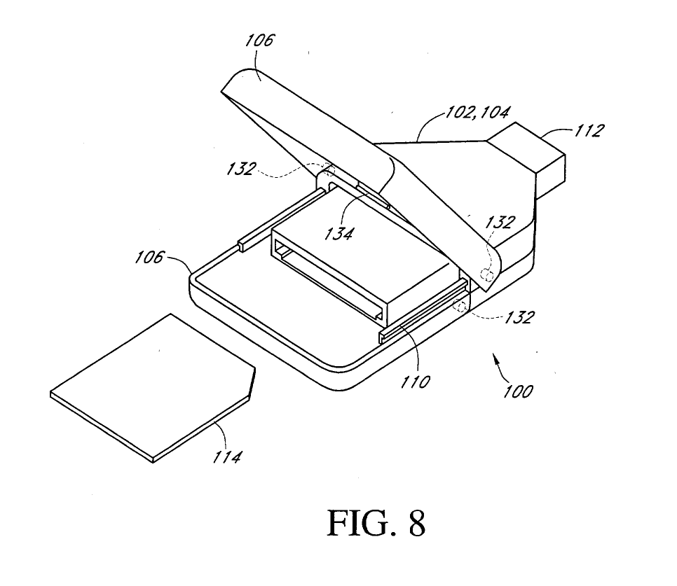

FIG. 8 illustrates another embodiment of a removable storage device 100 embodied as an adapter 102 including a housing 104 and covers 106. FIG. 8 illustrates the removable storage device 100 with one cover 106 in an open configuration so as to receive or remove a memory card 114 and with the other cover 106 closed. In this embodiment, the covers 106 are in a clamshell arrangement and can be independently opened/closed. In this embodiment, the covers 106 are pivotably connected to the housing 104 such as via a pin and socket 132 or hinge 134 arrangement, such that each cover 106 pivots with respect to the housing 104 to assume the closed and open configurations. The pin and socket 132 comprises cooperating male and female structures that can be embodied in either of the housing 104 or covers 106 respectively. The hinge 134 is positioned along a pivot end of the covers 106 and can be positioned on the interior or exterior of the removable storage device 100. While both pin and socket 132 and hinge 134 structures are illustrated for completeness, in practice they need not be provided in combination.

In this embodiment, the covers 106 are also attached to the housing 104 so as to inhibit the loss of the covers 106 and in a simplified arrangement and connection therebetween as compared to the embodiments illustrated in FIGS. 5-7. The securing structure 110 illustrated in FIG. 8 also comprises a friction fit arrangement, however in other embodiments can also assume a tab and recess or snap arrangement or any other securing means as previously described.

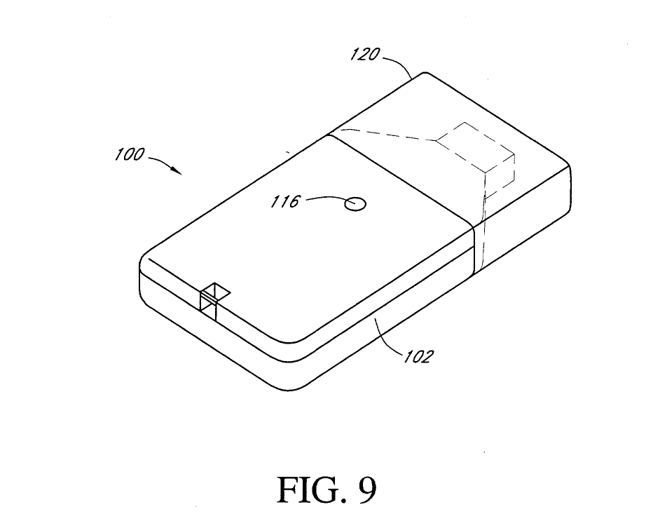

FIG. 9 illustrates a removable storage device 100 further comprising a connector cap 120. The connector cap 120 also has a generally rounded outer contour or profile and is adapted to securely fit over the connector 112 (illustrated in phantom) to provide additional protection to the connector 112. In particular, the connector cap 120 protects the connector 112 from exposure to dirt and other debris that may jam internal recesses of the connector 112 and also reduces potential exposure to contaminates or corrosive elements that may degrade the materials of the connector 112. The connector cap 120 is configured to fit securely to the rest of the removable storage device 100, such as via a friction or snap fit. FIG. 9 illustrates the connector cap 120 connected to an embodiment of the removable storage device 100 as illustrated in FIGS. 1-4, however the connector cap 120 is equally usable with the other embodiments of the removable storage device 100 previously described.

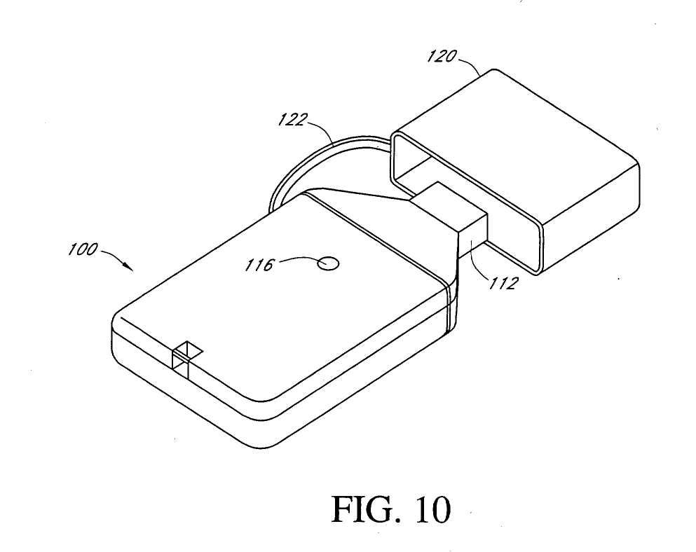

FIG. 10 illustrates an embodiment of a removable storage device 100 including the cap 120 with a tether 122 interconnecting the connector cap 120 to the rest of the removable storage device 100. One aspect of this embodiment is that when the connector cap 120 is detached from the rest of the removable storage device 100 it remains connected via the flexible tether 122 such that the connector 112 can be readily connected to a host system 200 and the tether 122 retains the connector cap 120 to reduce the risk of loss of the connector cap 120. In this embodiment the tether 122 is illustrated as a flexible ribbon material, such as can be made from plastic. However, it will be appreciated that in other alternative embodiments the tether 122 can comprise wire, string, elastic material, and/or a hinged structure to allow the connector cap 120 to be distanced from the rest of the removable storage device 100 so as to allow access to the connector 112.

FIG. 11 illustrates schematically a removable storage device 100 connected to a host system 200 which is illustrated in phantom. As previously described, in various embodiments the host system 200 can comprise electronic devices such as digital still and/or movie cameras, computer systems, personal digital assistants (PDAs), music players, game consoles, or other electronic devices that create, receive, process and/or store digital information. Another embodiment illustrated in FIGS. 11-13 is a pivotable connection between the connector 112 and the rest of the removable storage device 100. In this embodiment, the removable storage device is connected to the host system 200 via the connector 112 generally along an axis of connection, e.g. along axis A. The connector 112 and the rest of the removable storage device 100 are pivotable with respect to each other along at least one axis B that, in this embodiment, is substantially transverse to the insertion axis A.

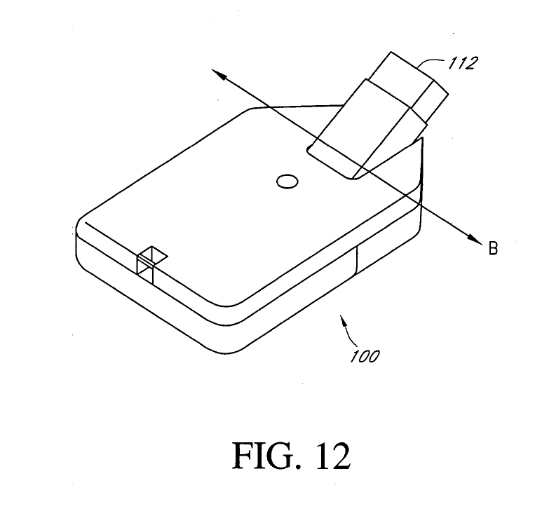

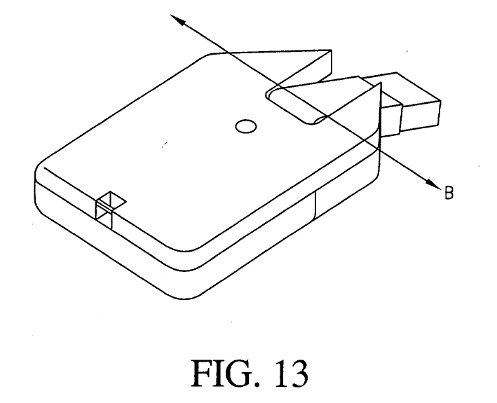

This embodiment, as can be seen in. FIGS. 12 and 13, allows the connector 112 to be pivoted upward or downward with respect to the rest of the removable storage device 100. While FIGS. 11-13 illustrate the pivoting axis B as arranged generally horizontally, in other embodiments, the pivoting axis can be arranged generally vertically or in other orientations. This embodiment of the invention provides the advantage that the connector 112 may be manipulated with respect to the rest of removable storage device 100 to provide clearance in applications where access to the host system 200 may be restricted by the placement of other objects.

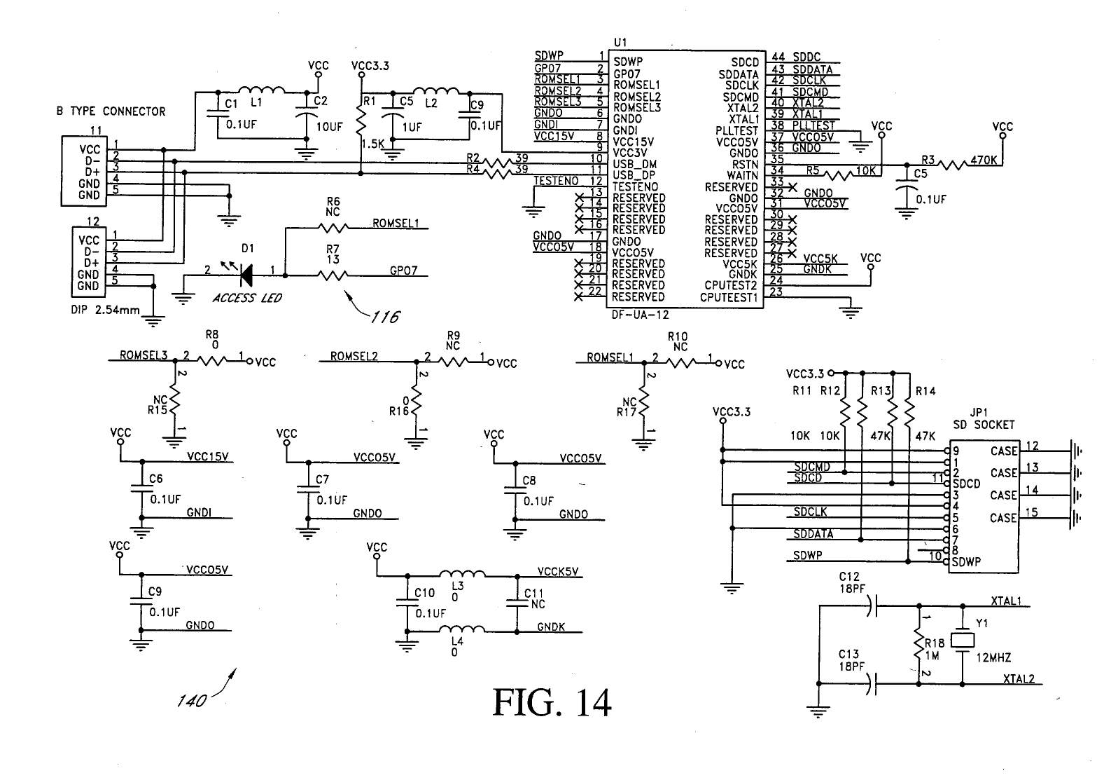

FIG. 14 is a circuit schematic for one embodiment of an interface circuit 140 adapted to provide communication between the memory card 114 and the host system 200 via the connector 112. As previously described, the connector 112 is preferably configured as a common and industry standard connector format such as the previously described USB or other connector standards. The embodiment of the interface circuit 140 illustrated in FIG. 14 is adapted to conform with the USB standard. As previously mentioned, the form factors, pin definitions, and electrical/electromagnetic characteristics of the USB format as well as other industry standard connector standards are well known to one of ordinary skill in the art and it will be appreciated that the interface circuit 140 illustrated in FIG. 14 is simply one embodiment and that other versions of the interface circuit 140 may be provided for specific applications without detracting from the scope of the invention.

Although the preferred embodiments of the present invention have shown, described and pointed out the fundamental novel features of the invention as applied to those embodiments, it will be understood that various omissions, substitutions and changes in the form of the detail of the device illustrated may be made by those skilled in the art without departing from the spirit of the present invention. Consequently, the scope of the invention should not be limited to the foregoing description but is to be defined by the appended claims.

What is claimed is:

1. An adapter for removable memory cards, the adapter comprising:
a housing configured to receive a memory card;
a connector for connection to a host system and associated with the housing;
an interface circuit interconnecting the memory card and connector and adapted to allow communication therebetween; and
at least one movable cover pivotably engaged with the housing and which, in a closed position, with the housing, defines a substantially enclosed cavity configured to retain the memory card.

2. The adapter of claim 1, wherein the housing is configured to receive a solid state memory card.

3. The adapter of claim 2, wherein the housing is configured to receive a Secure Digital (SD) memory card.

4. The adapter of claim 1, wherein the housing is configured to receive a microdrive memory card.

5. The adapter of claim 1, wherein at least one of the housing and cover comprise a securing structure to secure the cover in the closed position.

6. The adapter of claim 5, wherein the securing structure comprises a tab and corresponding recess.

7. The adapter of claim 1, wherein the connector comprises a Universal Serial Bus (USB) connector.

8. The adapter of claim 1, wherein the connector comprises a FireWire connector.

9. The adapter of claim 1, wherein the connector comprises a wireless connector.

10. The adapter of claim 1, wherein the interface circuit receives operating power from the host system.

11. The adapter of claim 1, wherein the cover and housing comprise mating post and socket structures.

12. The adapter of claim 1, wherein the cover and housing comprise mating leg and slot structures.

13. The adapter of claim 12, wherein the leg structure is substantially straight.

14. The adapter of claim 1, wherein the cover is pivotable and slidable with respect to the housing.

15. The adapter of claim 1, wherein at least one of the cover and housing has a region of non-zero transmittance such that the presence of the memory card in the reader may be visually determined.

16. The adapter of claim 1, comprising two covers arranged in a clamshell configuration.

17. The adapter of claim 1, further comprising a removable connector cap that substantially covers the connector.

18. The adapter of claim 16, wherein the connector cap is tethered to the rest of the adapter.

19. The adapter of claim 1, further comprising an indicator which provides a signal when the adapter is operationally connected to the host system.

20. The adapter of claim 19, wherein the indicator provides a signal when the memory card is in active communication with the host system.

21. The adapter of claim 1, comprising a memory card inserted into the housing so as to be in communication with the connector via the interface circuit.

22. An adapter for removable memory cards, the adapter comprising:
a housing configured to receive a memory card;
a connector for connection to a host system and associated with the housing;
an interface circuit interconnecting the memory card and connector and adapted to allow communication therebetween; and
at least one movable cover engaged with the housing wherein the cover and housing define a generally rounded exterior profile.

23. A removable storage device connectable to a host system, the device comprising:
a memory card;
a housing configured to receive the memory card;
a connector for connection to a host system and associated with the housing;
an interface circuit interconnecting the memory card and connector and adapted to allow communication therebetween; and
at least one movable cover engaged with the housing such that the cover is pivotable with respect to the housing and, in a closed position, defines a substantially enclosed cavity configured to retain the memory card.

24. A removable storage device connectable to a host system, the device comprising:
a memory card;
a housing configured to receive the memory card;
a connector for connection to a host system and associated with the housing;
an interface circuit interconnecting the memory card and connector and adapted to allow communication therebetween; and
at least one movable cover engaged with the housing wherein the cover and housing define a generally rounded exterior profile.

25. An adapter for removable memory cards, the adapter comprising:
a housing configured to receive a memory card;
a connector for connection to a host system along a connection axis and pivotably connected to the housing along at least an axis substantially transverse to the connection axis;
an interface circuit interconnecting the plurality of card contacts and connector and adapted to allow communication therebetween; and
at least one movable cover engaged with the housing.

26. An adapter for removable memory cards, the adapter comprising:
a housing configured to receive a memory card;
a connector for connection to a host system and associated with the housing;
an interface circuit interconnecting the memory card and connector and adapted to allow communication therebetween; and
multiple movable covers which are pivotably engaged with the housing and which, in a closed position, with the housing, define a substantially enclosed cavity configured to retain the memory card.

27. An adapter for removable memory cards, the adapter comprising:
a housing configured to receive a memory card; and
multiple movable covers which are pivotably engaged with the housing and which, in a closed position, with the housing, defines a substantially enclosed cavity configured to retain the memory card.

28. A memory card reader that interfaces with a universal serial bus (USB) connector, the memory card reader comprising:
a housing configured to receive different types of removable flash memory card;
a USB connector connected to the housing, said USB connector configured to connect to a host system;
interface circuitry that interconnects the different types of removable flash memory cards and the USB connector and is adapted to allow communication therebetween; and
at least one movable cover pivotably engaged with the housing and which, in a closed position, with the housing, defines a substantially enclosed cavity configured to retain the removable flash memory card and which in an open position allows removal of the removable flash memory card.
